(19) United States
(12) Patent Application Publication
(10) Pub. No.: US 2022/0034602 A1
(43) Pub. Date: Feb. 3, 2022

(54) HEAT EXCHANGER

(71) Applicant: Robert Bosch GmbH, Stuttgart (DE)

(72) Inventor: Martin Koehne, Asperg (DE)

(21) Appl. No.: 17/290,819

(22) PCT Filed: Oct. 14, 2019
(86) PCT No.: PCT/EP2019/077755

§ 371 Date: May 3, 2021

(30) Foreign Application Priority Data
Nov. 5, 2018 (DE) 10 2018 218 826.2

(51) Int. Cl. F28F 1/12; F28F 3/02; H05K 7/20

(52) U.S. Cl. CPC F28F 1/122; H05K 7/20336; F28F 3/022

(57) ABSTRACT

The invention relates to a heat exchanger (1) having a main part (2), which is thermally coupled to carbon nanostructure-based fibers (CNB), in particular carbon nanotubes (CNT). At least one gas channel (3) is provided and is formed by the main part (2) to at least some, the carbon nanostructure-based fibers (CNB) at least partially extending through the gas channel (3).

### BACKGROUND OF THE INVENTION

The invention relates to a heat exchanger.

US 2007 15 85 84 A has disclosed a heat sink comprising a main body from which a multiplicity of carbon nanotubes extend.

### SUMMARY OF THE INVENTION

In the field of electrical engineering, especially in high performance electronics, output peaks which result in large amounts of heat from the high performance electronic components occur during operation, for example in electric vehicles. These amounts of heat must be dissipated. This has hitherto been achieved through liquid cooling. Such cooling systems are complex and costly, since the necessary components such as cooling circuit, cooling water and pump generate considerable additional weight and considerable costs.

The invention relates to a heat exchanger having a main body which is in thermal communication with carbon nanostructure-based fibers which are especially produced from carbon nanotubes or graphene/graphite platelets. At least one gas channel which is at least partially formed by the main body is provided, wherein the carbon nanostructure-based fibers at least in regions extend in the gas channel. The gas channel results in very efficient cooling. The invention is elucidated hereinbelow with reference to a cooling. However, the invention also encompasses the configuration in the form of a heating, i.e. in such a case a component in thermal communication with the main body is heated by means of a gas heating stream flowing through the gas channel. In the case of cooling, a component to be deheated in thermal communication with the main body, in particular a high performance electronic element, emits its heat to the main body, i.e. the gas channel, wherein the gas channel, more particularly: at least one portion of a wall of the gas channel, transfers the heat to the carbon nanostructure-based fibers which at least in regions are present in the gas channel. The deheating according to the invention of high performance electronics is thus preferably carried out against the ambient air as the heat sink. An optional medium channel uses cooling liquid (coolant) to pass the heat from the high performance electronics to the gas channel. In the gas channel, the heat is transferred from the fibers into the gas/the air. The main body is in thermal communication with the carbon nanostructure-based fibers/yarns. The term “gas channel” describes the channel in which the carbon nanostructure-based fibers are located. The very large surface area greatly facilitates heat transfer into the gas (in particular air) and thus increases efficiency. The medium channel is in particular liquid-traversable. It serves to connect a heat source with the heat sink (i.e. the gas channel). Forced convection of the coolant is especially employed, preferably a blower which blows for example air through the medium channel, in particular gas channel, so that the recited disadvantages of liquid cooling do not occur. The invention nevertheless achieves very effective and cost-efficient cooling.

A development of the invention provides that the carbon nanostructure-based fibers extend along the cross section, in particular a cross-sectional area, preferably cross-sectional plane, of the gas channel, wherein the cross section extends transversely, in particular perpendicularly, to the longitudinal extent of the gas channel. As a result of this configuration, the cooling medium stream, in particular the cooling air, impacts the carbon nanostructure-based fibers transversely, thus achieving very good heat dissipation.

In a preferred development of the invention, the heat exchanger is directly connected to a heat source. The heat source is for example in direct contact with a wall section of the heat exchanger to ensure direct heat transfer from the heat source to the heat exchanger. Alternatively, the heat exchanger preferably comprises—as mentioned previously—a medium channel which is traversable or traversed by a cooling liquid for indirect connection to the heat source. The cooling liquid transports the heat from the heat source to the heat exchanger and thus provides the indirect connection. The cooling liquid advantageously flows in the direction from the heat source to the heat exchanger.

A development of the invention provides that the carbon nanostructure-based fibers at least in regions extend substantially parallel to one another. The carbon nanostructure-based fibers thus form a kind of parallel structure in the gas channel.

It may preferably be provided that the carbon nanostructure-based fibers form a net, preferably in the manner of a wire mesh. In this case, a network structure then takes the place of the recited parallel structure.

It may especially be provided that the carbon nanostructure-based fibers form a braid. The fibers are braided with one another, thus also providing them with improved mechanical stability and ensuring they are not deformed by the gas stream.

It may preferably be provided that the carbon nanostructure-based fibers form a weave.

It is preferably provided that the carbon nanostructure-based fibers form a knit.

The various measures such as for example the braid, the weave or the recited knit ensure a particularly large surface area of the structure formed by the carbon nanostructure-based fibers in the gas channel, thus improving heat dissipation.

It is advantageous when the carbon nanostructure-based fibers are directly connected to the main body. In such a case, the main body can directly emit its heat to the carbon nanostructure-based fibers.

It may preferably be provided that the carbon nanostructure-based fibers are held by a thermally conductive holder body which is arranged in the gas channel and is in thermal communication therewith. During construction of the heat exchanger, the carbon nanostructure-based fibers are thus secured to a holder body, wherein the latter is in turn arranged in the gas channel. This simplifies production. When arranging the holder body in the medium channel, said holder body is put into thermal communication with the latter so that the main body can transfer its heat to the holder body and said holder body can transfer to the carbon nanostructure-based fibers.

The holder body may preferably be configured as a holder frame. This holder frame is then “strung” with the carbon nanostructure-based fibers.

A development of the invention provides that a plurality of holder bodies and/or cross sections, in particular cross-sectional areas, formed by carbon nanostructure-based fibers are serially arranged in the gas channel along the longitudinal extent thereof. The plurality of holder bodies/plurality of cross sections altogether achieve a correspondingly large surface area of the carbon nanostructure-based fibers, with the result that the heat can be very well dissipated.

### BRIEF DESCRIPTION OF THE DRAWINGS

The invention is elucidated with reference to exemplary embodiments in the figures, in which:

FIG. 1 shows a cross section through a heat exchanger comprising carbon nanostructure-based fibers,

FIG. 2 shows the heat exchanger of FIG. 1 in cross section, but with a holder body for the carbon nanostructure-based fibers,

FIG. 3 shows another exemplary embodiment of a heat exchanger in cross section with fibers structured in a net-like fashion in the manner of a wire mesh, and

FIG. 4 shows a heat exchanger in cross section according to a further exemplary embodiment with carbon nanostructure-based fibers forming a weave.

### DETAILED DESCRIPTION

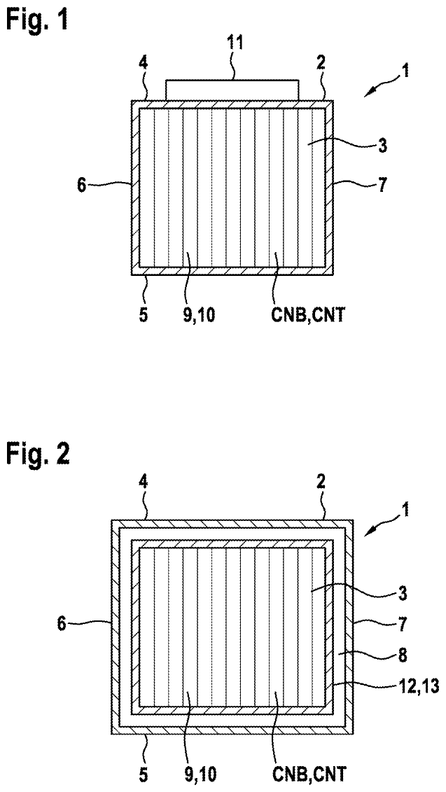

FIG. 1 is a schematic view of a heat exchanger 1 comprising a main body 2. The main body 2 is configured as a gas channel 3. The gas channel 3 has a rectangular, preferably square, cross section and thus two base walls 4 and 5 and two side walls 6 and 7. The base walls 4 and 5 are opposite one another in parallel and the side walls 6 and 7 are likewise opposite one another in parallel. The gas channel 3 is an air channel. This means that a cooling gas, preferably air, flows through it. The flow may be effected by natural convection or by forced convection, for example by means of a blower (not shown).

The gas channel 3 has a cross section 9. Located in a cross-sectional plane 10 which extends perpendicularly to the longitudinal extent of the gas channel 3 are a multiplicity of carbon nano-based fibers (CNB) which are in the form of carbon nanotubes (CNT). In the exemplary embodiment of FIG. 1, the carbon nanostructure-based fibers (CNB) extend substantially parallel to one another. Said fibers extend between the two base walls 4 and 5, preferably over the entire cross-sectional plane 10, i.e. a multiplicity of carbon nanostructure-based fibers (CNB) extend parallel to one another over the entire width of the gas channel 3. The carbon nanostructure-based fibers (CNB) are in thermal communication with the gas channel 3.

Arranged on the outside of the gas channel 3, in the exemplary embodiment of FIG. 1 on the base wall 4, is an article 11 which becomes hot in operation and may be in the form of a high performance electronic component, for example. When this article 11 becomes hot in operation, it emits its heat to the medium channel 3. From the medium channel 3, the heat then passes to the thermally very conductive carbon nanostructure-based fibers (CNB), in particular carbon nanotubes (CNT). A gas stream (not shown) flowing through the medium channel 3 dissipates the heat from the carbon nanostructure-based fibers (CNB).

The exemplary embodiment of FIG. 2 corresponds substantially to the exemplary embodiment of FIG. 1. In FIGS. 2 to 4, the article 11 is not shown for the sake of simplicity. The carbon nanostructure-based fibers (CNB) are in thermal communication with a thermally conductive holder body 12 which is in the form of a holder frame 13. In the exemplary embodiment of FIG. 2, carbon nanostructure-based fibers (CNB) are arranged extending parallel to one another on the holder frame 13. The holder frame 13 is arranged on the main body 2, preferably such that the frame cross-sectional area is perpendicular to the longitudinal extent of the main body 2. The exemplary embodiment of FIG. 2 has the advantage that the stringing of the holder frame 13 with the carbon nanostructure-based fibers (CNB) may be carried out outside the main body 2. Once this has been done, the strung holder frame 13 is inserted in the main body 2. The inserting is carried out such that there is thermal communication between the holder frame 13 and the main body 2. Press-fitting of the holder frame 13 in the main body 2 is conceivable. In the present exemplary embodiment, the heat exchanger 1 further comprises a medium channel 8 which especially passes cooling medium liquid from a heat source to the heat exchanger 1.

Not shown is an exemplary embodiment which corresponds to FIG. 1 or 2 and differs therefrom in that a plurality of fiber cross sections or holder frames 13 are serially arranged in the main body 2 along the longitudinal extent thereof. This brings about a corresponding enlargement of the surface area of the carbon nanostructure-based fibers (CNB).

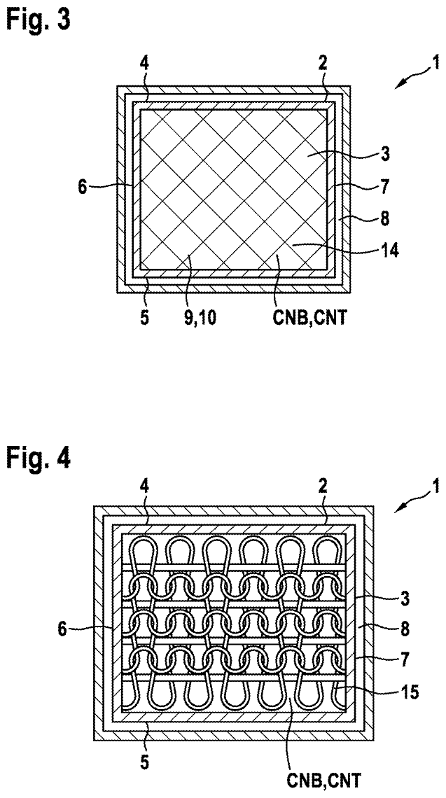

The exemplary embodiment of FIG. 3 corresponds to the exemplary embodiment of FIG. 2, but differs therefrom merely in that the carbon nanostructure-based fibers (CNB) do not extend parallel to one another, but instead form a net 14, preferably in the manner of a wire mesh.

The exemplary embodiment of FIG. 4 comprises a heat exchanger 1 corresponding to FIG. 1, but likewise does not employ carbon nanostructure-based fibers (CNB) extending parallel to one another, instead rather a weave 15 consisting of carbon nanostructure-based fibers (CNB).

The invention is especially employable in the field of electric vehicles, namely for cooling output peaks of high performance electronic components. It is preferable when forced convection of air is generated in the medium channel 3 using a blower. The large heat exchanger surface area generated by the carbon nanostructure-based fibers (CNB) is advantageous, this ensuring very good heat transfer from the solid to the flowing gas, especially to the flowing air. It is preferable to employ carbon nanostructure-based fibers (CNB), in particular fibers composed of CNT or graphene platelets, having a diameter of 5 μm and especially having a thermal conductivity >800 W/mK. In addition, such a material has a very high tensile strength >1 GPa, thus making it possible to realize very delicate structures having sufficient resilience. It is further advantageous that textile methods, such as knitting, braiding or weaving, may be employed to achieve structures with the carbon nanostructure-based fibers (CNB) through which the cooling medium, namely the cooling gas, in particular the air, may flow. Such textile elements are also particularly amenable to prefabrication.

Employed for example is a heat exchanger 1 provided with a holder frame 13, wherein the holder frame 13 has a width of 10 cm and a height of 3 cm. Said frame can accommodate preferably 2000 windings of the carbon nanostructure-based fibers (CNB). These carbon nanostructure-based fibers (CNB) especially have a diameter of 10 μm. Such a holder frame 13 results in a heat exchanger surface area of 0.0037 m². When about 30, preferably 33, such holder frames 13 are serially arranged in a medium channel 3 of a heat exchanger 1, this results in a heat exchanger surface area of 0.124 m². This makes it possible to realize an effective heat exchanger 1 even in a small space and by the simplest means of production.

The same applies to heat exchangers 1 which comprise carbon nanostructure-based fibers (CNB) in the form of a braid of a net cloth (in particular wire mesh) or which comprise a knit or weave. A knit or weave preferably comprises numerous weft threads, since these form a direct connection with the medium channel 3.

The highly efficient heat exchangers 1 according to the invention are—as mentioned—employable especially in high performance electronics. However, further applications include air-conditioning systems, household appliances and the like. As mentioned hereinabove, such heat exchangers 1 are suitable not only for cooling, but also for heating.

1. A heat exchanger (1) having a main body (2) which is in thermal communication with carbon nanostructure-based fibers (CNB), characterized by at least one gas channel (3) which is at least partially formed by the main body (2), wherein the carbon nanostructure-based fibers at least in regions extend in the gas channel (3).

2. The heat exchanger as claimed in claim 1, characterized in that the carbon nanostructure-based fibers (CNB) extend along the cross section (9) of the gas channel (3), wherein the cross section (9) extends transversely to the longitudinal extent of the gas channel (3).

3. The heat exchanger as claimed in claim 1, characterized in that the heat exchanger (1) is directly connected or connectable to a heat source.

4. The heat exchanger as claimed in claim 1, characterized in that the carbon nanostructure-based fibers (CNB) at least in regions extend substantially parallel to one another.

5. The heat exchanger as claimed in claim 1, characterized in that the carbon nanostructure-based fibers (CNB) form a net (14).

6. The heat exchanger as claimed in claim 1, characterized in that the carbon nanostructure-based fibers (CNB) form a braid.

7. The heat exchanger as claimed in claim 1, characterized in that the carbon nanostructure-based fibers (CNB) form a weave (15).

8. The heat exchanger as claimed in claim 1, characterized in that the carbon nanostructure-based fibers (CNB) form a knit.

9. The heat exchanger as claimed in claim 1, characterized in that the carbon nanostructure-based fibers (CNB) are directly connected to the main body (2).

10. The heat exchanger as claimed in claim 1, characterized in that the carbon nanostructure-based fibers (CNB) are held by a thermally conductive holder body (12) which is arranged in the main body (2) and is in thermal communication therewith.

11. The heat exchanger as claimed in claim 10, characterized in that the holder body (12) is a holder frame (13).

12. The heat exchanger as claimed in claim 1, characterized in that a plurality of holder bodies (12) and/or cross sections (9) formed by carbon nanostructure-based fibers (CNB) are serially arranged in the main body (2) along the longitudinal extent thereof.

13. The heat exchanger as claimed in claim 1, wherein the carbon nanostructure-based fibers (CNB) are carbon nanotubes (CNT).

14. The heat exchanger as claimed in claim 1, characterized in that the carbon nanostructure-based fibers (CNB) extend along a cross-sectional area of the gas channel (3), wherein the cross-sectional area extends transversely to the longitudinal extent of the gas channel (3).

15. The heat exchanger as claimed in claim 1, characterized in that the carbon nanostructure-based fibers (CNB) extend along a cross-sectional plane (10) of the gas channel (3), wherein the a cross-sectional plane (10) extends transversely to the longitudinal extent of the gas channel (3).

16. The heat exchanger as claimed in claim 1, characterized in that the carbon nanostructure-based fibers (CNB) extend along a cross-section of the gas channel (3), wherein the cross section (9) extends perpendicularly to the longitudinal extent of the gas channel (3).

17. The heat exchanger as claimed in claim 1, characterized in that the carbon nanostructure-based fibers (CNB) extend along a cross-sectional plane (10) of the gas channel (3), wherein the a cross-sectional plane (10) extends perpendicularly to the longitudinal extent of the gas channel (3).

18. The heat exchanger as claimed in claim 1, characterized in that the heat exchanger (1) comprises a medium channel (8) which is traversable or traversed by a cooling liquid for indirect connection to the heat source.

19. The heat exchanger as claimed in claim 1, characterized in that the carbon nanostructure-based fibers (CNB) form a wire mesh.

20. The heat exchanger as claimed in claim 1, characterized in that a plurality of holder bodies (12) and/or cross cross-sectional areas, formed by carbon nanostructure-based fibers (CNB) are serially arranged in the main body (2) along the longitudinal extent thereof.
